(19) United States
(12) Patent Application Publication
(10) Pub. No.: US 2026/0248039 A1
(43) Pub. Date: Aug. 20, 2026

(54) HIGH BANDWIDTH MEMORY DEVICES, SYSTEMS, AND FABRICATION METHODS THEREOF

(71) Applicant: Yangtze Memory Technologies Holding Co., Ltd., Wuhan (CN)

(72) Inventors: Tingting GAO, Wuhan (CN); Dongyu FAN, Wuhan (CN); Lei LIU, Wuhan (CN)

(21) Appl. No.: 19/176,328

(22) Filed: Apr. 11, 2025

(30) Foreign Application Priority Data
Feb. 20, 2025 (CN) 202510192117.2

(51) Int. Cl. H10W 90/00; H10B 80/00; H10D 80/30; H10W 20/00; H10W 20/42; H10W 90/20

(52) U.S. Cl. CPC H10W 90/00; H10B 80/00; H10D 80/30; H10W 20/056; H10W 20/076; H10W 20/082; H10W 20/42; H10W 90/297; H10W 90/732

(57) ABSTRACT

The present disclosure relates methods, devices, systems, and techniques for high bandwidth memory (HBM). A semiconductor device includes multiple semiconductor structures including a first semiconductor structure having a first conductive layer and a second semiconductor structure having a second conductive layer. The semiconductor device also includes multiple contact structures including a first contact structure that extends into the first semiconductor structure and contacts the first conductive layer and a second contact structure that contacts the second conductive layer. The semiconductor device further includes a conductive structure including a first body that surrounds the first contact structure. The first body and the first conductive layer are separated by a dielectric layer.

### CROSS-REFERENCE TO RELATED APPLICATIONS

This application claims priority to Chinese Patent Application No. 202510192117.2, filed on February 20, 2025, which is hereby incorporated by reference in its entirety.

### TECHNICAL FIELD

The present disclosure relates to high bandwidth memory (HBM) systems and devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

A high bandwidth memory (HBM) uses stacked memory devices to enable effective data movement and access. While using less power in a smaller form factor, HBM devices can achieve higher bandwidth. HBM devices have been applied to high-performance graphics accelerators, network devices, high-performance datacenter, artificial intelligence (AI) and machine learning (ML) training, and various supercomputers.

### SUMMARY

The present disclosure describes methods, devices, systems and techniques for high bandwidth memory (HBM).

One aspect of the present disclosure features a semiconductor device. The semiconductor device includes multiple semiconductor structures stacked along a first direction, where the multiple semiconductor structures include a first semiconductor structure including a first conductive layer and a second semiconductor structure including a second conductive layer. The semiconductor device also includes multiple contact structures extending along the first direction, where the multiple contact structures include a first contact structure and a second contact structure, the first contact structure extends into the first semiconductor structure and contacts the first conductive layer, the second contact structure contacts the second conductive layer; and a conductive structure including a first body, where the first body surrounds the first contact structure and extends into the first semiconductor structure along the first direction, and the first body and the first conductive layer are separated by a dielectric layer.

In some implementations, the conductive structure includes a conductive material and is configured to be coupled to a lower level voltage.

In some implementations, the semiconductor device further including a first insulation layer between the first contact structure and the first body and a second insulation layer between the second contact structure and the second body, where the first insulation layer and the second insulation layer include a same dielectric material.

In some implementations, a thickness of each of the first insulation layer and the second insulation layer along a second direction perpendicular to the first direction is in a range between 1 nanometer (nm) and 100 nm.

In some implementations, the conductive structure further includes a base and a second body, the base is perpendicular to the first direction, the first body and the second body contact the base, the second body surrounds the second contact structure and extends through the first conductive layer along the first direction, and a dielectric material is between the second body and the second conductive layer, and between the second body and the first conductive layer.

In some implementations, the semiconductor devices includes one or more bonding structures including a first bonding structure between the first semiconductor structure and the second semiconductor structure. The first semiconductor structure and the second semiconductor structure are bonded through the first bonding structure, and the first bonding structure includes a dielectric material. The second contact structure extends through the first bonding structure along the first direction. The second body extends through the first bonding structure along the first direction.

In some implementations, the first conductive layer is aligned with the second conductive layer along the first direction, the first conductive layer is included in an interconnect layer of the first semiconductor structure, and the second conductive layer is included in an interconnect layer of the second semiconductor structure.

In some implementations, the multiple semiconductor structures further include a third semiconductor structure, where the first semiconductor structure, the second semiconductor structure, and the third semiconductor structure are stacked along the first direction, and the third semiconductor structure includes a third conductive layer; the one or more bonding structures further include a second bonding structure between the second semiconductor structure and the third semiconductor structure, where the second semiconductor structure and the third semiconductor structure are bonded through the second bonding structure; the multiple contact structures further include a third contact structure, where the third contact structure extends through the first conductive layer, the second conductive layer, the first bonding structure, and the second bonding structure and contacts the third conductive layer; and the conductive structure further includes a third body extending along the first direction, where the third body surrounds the third contact structure, extends through the first conductive layer, the second conductive layer, the first bonding structure, and the second bonding structure, and contacts the base without contacting the first conductive layer, the second conductive layer, and the third conductive layer.

In some implementations, a size of each of the first body, the second body, and the third body along a second direction perpendicular to the first direction is in a range between 0.5 micrometers (µm) and 10 µm, and a pitch between the first body, the second body, and the third body is in a range between 0.5 µm and 10 µm.

In some implementations, a thickness of each of the first body, the second body, and the third body along the second direction is in a range between 1 nanometer (nm) and 100 nm.

In some implementations, the at least one of the first semiconductor structure or the second semiconductor structure is a dynamic random-access memory (DRAM) device.

In some implementations, the DRAM device includes an array structure and a peripheral structure, the array structure includes an array of DRAM cells, at least one DRAM cell of the array structure includes a transistor and a capacitor, and the peripheral structure includes a peripheral circuit configured to control the array of DRAM cells.

Another aspect of the present disclosure features a semiconductor device. The semiconductor device includes multiple semiconductor structures stacked along a first direction, where the multiple semiconductor structures include a first semiconductor structure including a first conductive layer and a second semiconductor structure including a second conductive layer. The semiconductor device also includes multiple contact structures extending along the first direction, where the multiple contact structures include a first contact structure and a second contact structure, the first contact structure extends into the first semiconductor structure and contacts the first conductive layer, the second contact structure contacts the second conductive layer; and a conductive structure including a first body, where the first body surrounds the first contact structure and extends into the first semiconductor structure along the first direction, and the first body and the first conductive layer are separated by a dielectric layer.

In some implementations, a first end of the first conductive layer and a first end of the second conductive layer are offset along a second direction perpendicular to the first direction.

In some implementations, the second contact structure and the second body are between the first end of the first conductive layer and the first end of the second conductive layer along the second direction.

In some implementations, the semiconductor device further includes: one or more bonding structures including a first bonding structure between the first semiconductor structure and the second semiconductor structure. The conductive structure further includes a base and a second body. The base is perpendicular to the first direction. The second contact structure extends through the first bonding structure. The second body surrounds the second contact structure, extends through the first bonding structure along the first direction, and contacts the base. A dielectric material is between the second body and the first conductive layer, and between the second body and the second conductive layer.

In some implementations, the at least one of the first semiconductor structure or the second semiconductor structure is a dynamic random-access memory (DRAM) device.

In some implementations, the DRAM device includes an array structure and a peripheral structure, the array structure includes an array of DRAM cells, at least one DRAM cell of the array structure includes a transistor and a capacitor, and the peripheral structure includes a peripheral circuit configured to control the array of DRAM cells.

A further aspect of the present disclosure features a method including forming a first semiconductor structure, and second semiconductor structure stacked along a first direction, where the first semiconductor structure includes a first conductive layer, the second semiconductor structure includes a second conductive layer; forming a first contact structure and a second contact structure extending along the first direction, where the first contact structure extends into the first semiconductor structure and contacts the first conductive layer, the second contact structure contacts the second conductive layer; and forming a conductive structure including a first body, where the first body surrounds the first contact structure and extends into the first semiconductor structure, and the first body and the first conductive layer are separated by a dielectric layer.

In some implementations, the method further includes forming a first bonding structure between the first semiconductor structure and the second semiconductor structure along the first direction; forming a first contact hole and a second contact hole extending along the first direction, where the first contact hole extends into the first semiconductor structure and reaches the first conductive layer, and the second contact hole extends through the first bonding structure and reaches the second conductive layer; and forming a first dielectric layer by depositing a dielectric material on top of the first semiconductor structure and in the first contact hole and the second contact hole.

In some implementations, the first conductive layer is aligned with the second conductive layer along the first direction; the second contact hole extends through the first conductive layer; and forming the first contact hole and the second contact hole includes forming the first contact hole and a first portion of the second contact hole by a first etching process, where the first contact hole and the first portion of the second contact hole both reach the first conductive layer; filling the first contact hole and the first portion of the second contact hole with a filler material; forming a mask on top of the first semiconductor structure, where the mask covers an opening of the first contact hole and includes a pattern that matches an opening of the second contact hole; removing the filler material in the first portion of the second contact hole; forming the second contact hole by a second etching process, where the second contact hole reaches the second conductive layer; and removing the mask and the filler material in the first contact hole.

In some implementations, a first end of the first conductive layer and a first end of the second conductive layer are offset along a second direction perpendicular to the first direction; the second contact hole is between the first end of the first conductive layer and the first end of the second conductive layer along the second direction; the second contact hole does not extend through the first conductive layer; and forming the first contact hole and the second contact hole includes forming the first contact hole and the second contact hole by a same etching process.

In some implementations, forming the conductive structure includes forming a conductive structure by depositing a conductive material on top of the first dielectric layer; and etching off a bottom portion of the conductive structure and the first dielectric layer in the first contact hole and a bottom portion of the conductive structure and the first dielectric layer in the second contact hole by a third etching process, where the third etching process exposes the first conductive layer in the first contact hole and exposes the second conductive layer in the second contact hole, where the first body of the conductive structure is formed by the conductive structure in the first contact hole, the second body of the conductive structure is formed by the conductive structure in the second contact hole, and a base of the conductive structure is formed by a remaining portion of the conductive structure on top of the first semiconductor structure.

In some implementations, the method further includes forming a second dielectric layer by depositing the dielectric material on top of the first semiconductor structure and in the first contact hole and the second contact hole; and etching off a bottom portion of the second dielectric layer in the first contact hole and a bottom portion of the second dielectric layer in the second contact hole by a fourth etching process, where the fourth etching process exposes the first conductive layer in the first contact hole and exposes the second conductive layer in the second contact hole.

In some implementations, forming the first contact structure and the second contact structure includes depositing the conductive material in the first contact hole and the second contact hole, where the first contact structure is formed by the conductive material in the first contact hole, and the second contact structure is formed by the conductive material in the second contact hole.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIGS. 1A - 1B illustrate cross-sectional view of example semiconductor devices, according to some aspects of the present disclosure.

FIG. 1C illustrates a top view of an example semiconductor device, according to some aspects of the present disclosure.

FIG. 1D illustrates a cross-sectional view of an example semiconductor device, according to some aspect of the present disclosure.

FIGS. 2A-2H illustrate an example process of manufacturing a semiconductor device, according to some aspects of the present disclosure.

FIGS. 3A-3H illustrate an example process of manufacturing a semiconductor device, according to some aspects of the present disclosure.

FIG. 4 illustrates a flow chart of an example process of forming a semiconductor device, according to some aspects of the present disclosure.

FIG. 5 illustrates a block diagram of an example system having one or more semiconductor devices.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to the increased demand for cheaper memory devices with higher density, a memory device (e.g., a high bandwidth memory (HBM)) can be formed to have an increased array density with multiple layers of the memory device stacked on top of each other. The high array density with layer stacking structure of the HBM memory requires more contact structures to connect to each layer of HBM memory. The large number of contact structures may pose challenges in signal integrity. A large number of ground shielding vias around the contact structures may be required to maintain signal integrity and ensure low loss between memory communications. The large number of ground shielding vias will take up a large chip area, increasing the fabrication cost and reducing the active area. Therefore, a new structure of the ground shielding vias for the contact structures that can reduce the fabrication cost with a low area for the memory device is desirable.

In one or more implementations of the present disclosure, an example semiconductor device is provided. The semiconductor device includes multiple semiconductor structures stacked along a first direction, where the multiple semiconductor structures include a first semiconductor structure including a first conductive layer and a second semiconductor structure including a second conductive layer. The semiconductor device also includes multiple contact structures extending along the first direction, where the multiple contact structures include a first contact structure and a second contact structure, the first contact structure extends into the first semiconductor structure and contacts the first conductive layer, the second contact structure contacts the second conductive layer; and a conductive structure including a first body, where the first body surrounds the first contact structure and extends into the first semiconductor structure along the first direction, and the first body and the first conductive layer are separated by a dielectric layer.

Implementations of the present disclosure can provide one or more of the following technical advantages and/or benefits. First, the body of the shielding surrounds each contact structure of the memory device and is connected to ground through the base of the shielding structures. In other words, each contact structure of the memory device is surrounded by a shielding structure that is connected to ground, which maintains the signal integrity of the communication of the memory device without the need for ground shielding vias around the contact structures. The elimination of the ground shield vias saves space for the memory device. Second, the shielding body can be fabricated within the same contact hole as the contact structures of the memory device, which simplifies the fabrication process and reduces the fabrication cost.

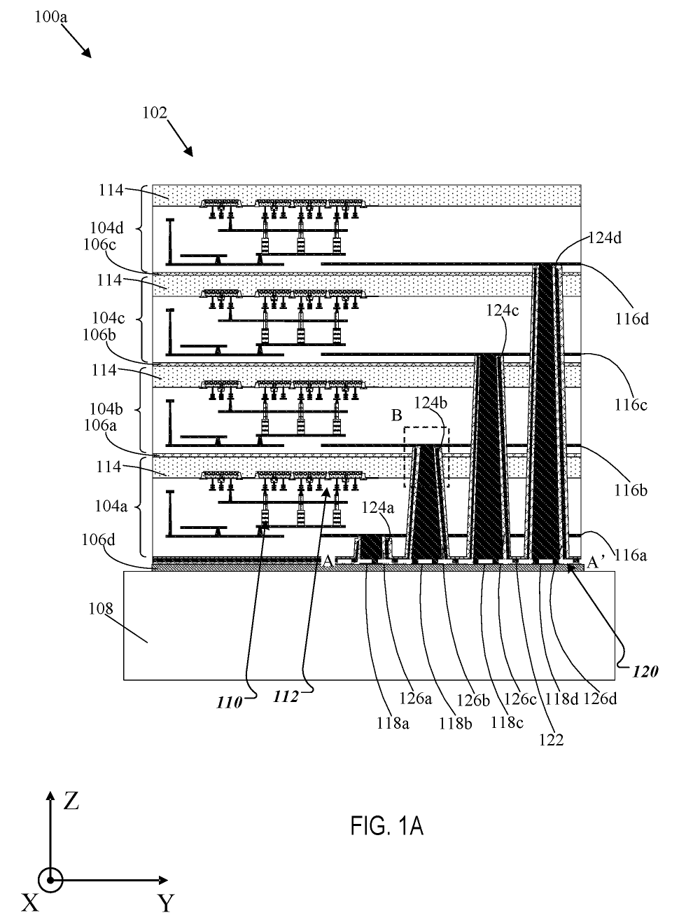

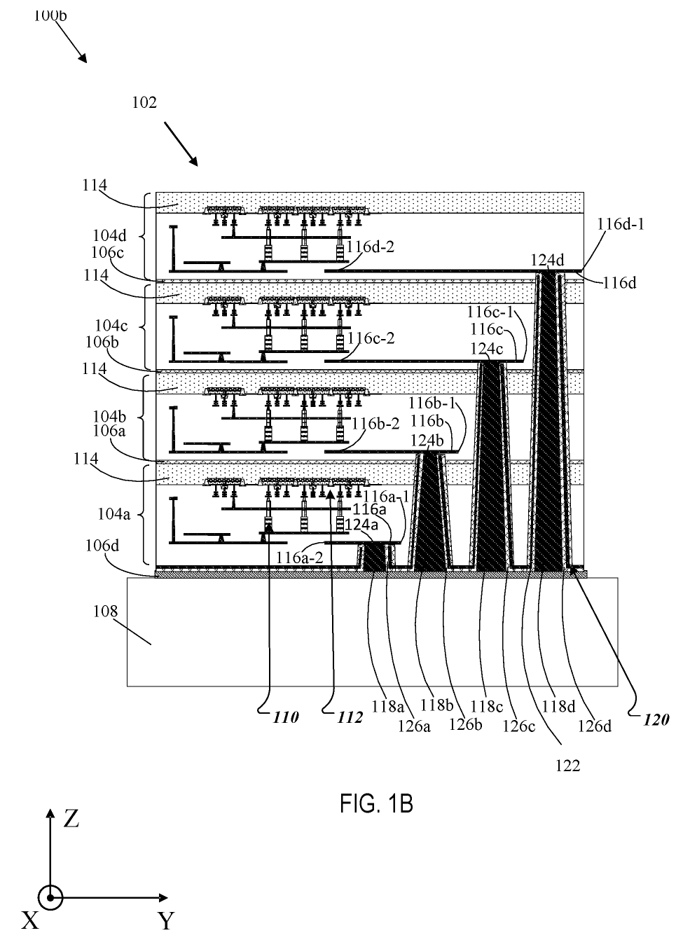

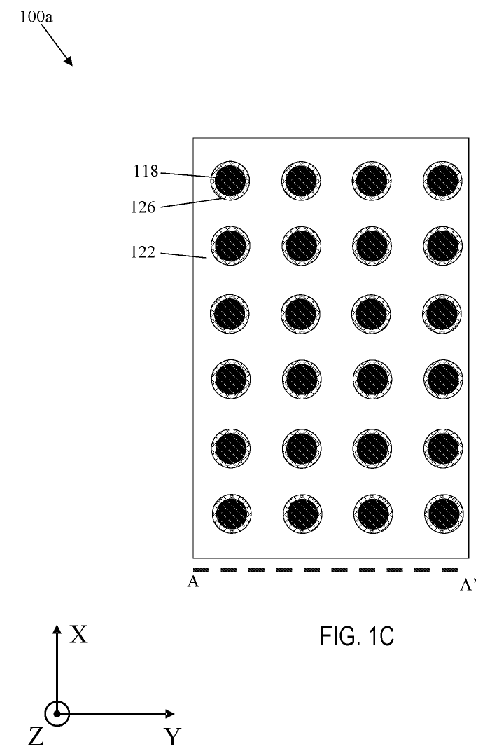

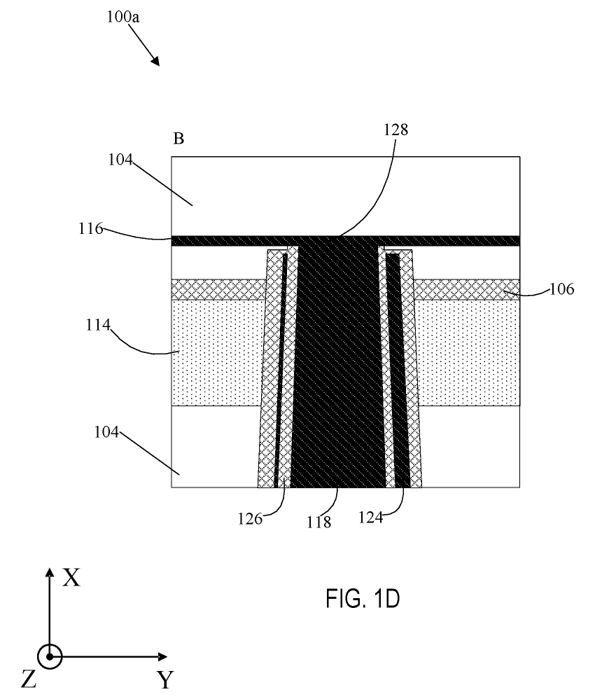

FIG. 1A illustrate a cross-sectional view of an example semiconductor device 100a, according to some aspects of the present disclosure. The semiconductor device 100a can be a memory device, e.g., an HBM. It is noted that X, Y, and Z axes (also referred to as X, Y, and Z directions) are included in FIG. 1A to further illustrate the spatial relationship of various components in a semiconductor device. A substrate of the semiconductor device includes two lateral surfaces extending laterally in the X-Y plane: a top surface on the front side of a wafer on which a component of the semiconductor device can be formed, and a bottom surface on the backside opposite to the front side of the wafer. The Z direction is perpendicular to both the X and Y directions. As used herein, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

As shown in FIG. 1A, the semiconductor device 100a includes a stack 102 of semiconductor structures 104a - 104d. Each of the semiconductor structures 104a - 104d can be a dynamic random-access memory (DRAM) die. The semiconductor structures 104a - 104d are stacked (e.g., sequentially) along a vertical direction (e.g., the Z direction).

The semiconductor device 100a includes bonding structures 106a - 106c. As shown in FIG. 1A, each of the bonding structures 106a - 106c is between two of semiconductor structures 104a - 104d. For example, as shown in FIG. 1A, the semiconductor structures 104a and 104b are bonded through bonding structure 106a. The semiconductor structures 104b - 104c are bonded through bonding structure 106b. The semiconductor structures 104c - 104d are bonded through bonding structure 106c. Each of the bonding structures 106a - c can include a top bonding layer and a bottom bonding layer bonded at a bonding interface. Each of the top bonding layer and the bottom bonding layer can include a dielectric material (including, but not limited to, silicon oxide, silicon nitride, silicon oxynitride, low-k dielectrics, or any combination thereof) and can exclude a conductive bonding contact. The semiconductor structure 104a can be bonded on top of the semiconductor structure 104b in a face-to-face manner through the bonding structure 106a. Bonding interface is disposed between the top bonding layer and the bottom bonding layer as a result of direct bonding (e.g., dielectric-dielectric bonding), which forms bonding between surfaces without using intermediate layers, such as solder or adhesives. In some implementations (not shown in FIG. 1A), for example, when the dielectric material of the top bonding layer and the dielectric material of the bottom bonding layer are different materials, bonding interface can be a visible layer with a certain thickness that includes a top surface of the bottom bonding layer and a bottom surface of the top bonding layer. In some implementations, as shown in the example of FIG. 1A, when the dielectric material of the top bonding layer and the dielectric material of the bottom bonding layer are the same material, bonding interface may not be visible and the top bonding layer and the bottom bonding layer may form a continuous bonding structure 106a.

In some implementations, as shown in FIG. 1A, the stack 102 of the semiconductor structures 104a - 104d are stacked on a base die 108 (also referred to as a logic die or a buffer die), which can include buffer circuitry and test logic for semiconductor device 100a. Base die 108 can be configured to provide physical layer communication protocols (e.g., IEEE-1500) between semiconductor device 100a cand a computing die. Base die 108 can be configured to transmit data between semiconductor device 100a and computing die based on control commands and addresses from computing die. In some implementations, the base die 108 is bonded to the stack 102 through a bonding structure 106d.

As shown in FIG. 1A, each of the semiconductor structures 104a - 104d in the stack 102 can include memory array 110 and a peripheral circuit 112. The memory array 110 can be included in an array structure of the semiconductor structure, and the peripheral circuit 112 can be included in a peripheral structure of the semiconductor structure. The memory array 110 can include an array of memory cells (e.g., DRAM cells). In some implementations, the peripheral circuit 112 is configured to control the array of the DRAM cells. At least one DRAM cell of the array of the DRAM cells can include a transistor and a capacitor. Each of the semiconductor structures 104a - 104d can include a substrate 114, which can include silicon (e.g., single crystalline silicon, c-Si), SiGe, GaAs, Ge, SOI, or any other suitable materials. The peripheral circuit 112 can be formed on or in the substrate 114 as shown in FIG. 1A. In some implementations, the substrate can be thinned down or removed in a later fabrication process.

As shown in FIG. 1A, each of the semiconductor structures 104a - 104d can also include conductive layers 116. For example, the semiconductor structure 104a can include a first conductive layer 116a, the semiconductor structure 104b can include a second conductive layer 116b and the semiconductor structure 104c can include a third conductive layer 116c. In some implementations, the number of the semiconductor structures 104 stacked on top of each other is more than 3 and each semiconductor structure 104 can include a corresponding conductive layer 116. For example, as shown in FIG. 1A, the semiconductor structure 104d can include a fourth conductive layer 116d.

As shown in FIG. 1A, the first conductive layer 116a, the second conductive layer 116b, the third conductive layer 116c, and the fourth conductive layer 116d of the conductive layers 116 are aligned with each other along the Z direction. Alternatively, in some implementations, the first conductive layer 116a, the second conductive layer 116b, the third conductive layer 116c, and the fourth conductive layer 116d of the conductive layers 116 may not be aligned with each other along the Z direction. In some implementations, the first conductive layer 116a is included in an interconnect layer of the semiconductor structure 104a. The second conductive layer 116b is included in an interconnect layer of the semiconductor structure 104b. The third conductive layer 116c is included in an interconnect layer of the semiconductor structure 104c. The fourth conductive layer 116d is included in an interconnect layer of the semiconductor structure 104d. An interconnect layer can include interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. For example, each conductive layer 116 can be or can include one or more interconnects in a corresponding interconnect layer. The interconnect layer can further include one or more interlayer dielectric (ILD) layers (also known as “intermetal dielectric (IMD) layers”) in which the interconnect lines and VIA contacts can form. That is, the interconnect layer can include interconnect lines and VIA contacts in multiple ILD layers. The interconnect lines and VIA contacts in the interconnect layer can include conductive materials including, but not limited to, tungsten (W), cobalt (Co), copper (Cu), aluminum (Al), silicides, or any combination thereof. The ILD layers in the interconnect layer can include dielectric materials including, but not limited to, silicon oxide, silicon nitride, silicon oxynitride, low dielectric constant (low-k) dielectrics, or any combination thereof.

The semiconductor device 100a can further include multiple contact structures 118 that extend along the Z direction. For example, as shown in FIG. 1A, the multiple contact structures 118 can include a first contact structure 118a, a second contact structure 118b and a third contact structure 118c, each of which can be in contact with a corresponding conductive layer 116 of the semiconductor structures 104a - 104c. For example, as shown in FIG. 1A, the first contact structure 118a extends into the semiconductor structure 104a and contacts the first conductive layer 116a. The second contact structure 118b extends through the bonding structure 106a and contacts the second conductive layer 116b. The third contact structure 118c extends through the first conductive layer 116a, the second conductive layer 116b, the bonding structure 106a and the bonding structure 106b and contacts the third conductive layer 116c. In some implementations, the number of the semiconductor structures 104 stacked on top of each other is more than 3 and the multiple contact structures 118 further include a fourth contact structure 118d that extends through the first conductive layer 116a, the second conductive layer 116b, the third conductive layer 116c, the bonding structure 106a, the bonding structure 106b, and the bonding structure 106c and contacts the third conductive layer 116c.

The semiconductor device 100a also includes a shielding structure 120 (also referred to as a conductive structure). The shielding structure 120 includes a base 122 and bodies 124. The bodies of the shielding structure 120 extend along the Z direction and are in contact with the base 122 of the shielding structure 120. The base 122 is in the semiconductor structure 104a and is perpendicular to the Z direction. In some implementations, the base 122 is in contact with a surface of the semiconductor structure 104a and can be considered being located outside of the semiconductor structure 104a. Each of the contact structures 118 has a corresponding body 124 of the shielding structure 120 that surrounds the corresponding contact structure 118 (e.g., along a direction perpendicular to the first direction). For example, as shown in FIG. 1A, a first body 124a of the shielding structure 120 surrounds the first contact structure 118a (e.g., along the Y direction), extends into the semiconductor structure 104a along the Z direction, and contacts the base 122 of the shielding structure 120 without contacting the first conductive layer 116a. The second body 124b of the shielding structure 120 surrounds the second contact structure 118b (e.g., along the Y direction), extends through the first conductive layer 116a and the bonding structure 106a, and contacts the base 122 of the shielding structure 120 without contacting the first conductive layer 116a and the second conductive layer 116b. The third body 124c of the shielding structure 120 surrounds the third contact structure 118c (e.g., along the Y direction), extends through the first conductive layer 116a, the second conductive layer 116b, the bonding structure 106a, and the bonding structure 106b, and contacts the base 122 without contacting the first conductive layer 116a, the second conductive layer 116b, and the third conductive layer 116c. Each of the contact structures 118a, 118b, and 118c can extend beyond a corresponding one of the bodies 124a, 124b, and 124c along the first direction. In some implementations, the number of the semiconductor structures 104 stacked on top of each other is more than 3 and the bodies 124 of the shielding structure 120 further includes a fourth body 124d that surrounds the fourth contact structure 118d, extends through the first conductive layer 116a, the second conductive layer 116b, the third conductive layer 116c, the bonding structure 106a, the bonding structure 106b, and the bonding structure 106c and contacts the base 122 without contacting the first conductive layer 116a, the second conductive layer 116b, the third conductive layer 116c, and the fourth conductive layer 116d. The shielding structure 120 includes a conductive material and is configured to be coupled to a lower level voltage (e.g., grounded). In some implementations, a size of each of the first body 124a, the second body 124b, the third body 124c, and the fourth body 124d of the bodies 124 of the shielding structure 120 is in a range between 0.5 micrometers (µm) and 10 µm, and a pitch between the first body 124a, the second body 124b, the third body 124c, and the fourth body 124d of the bodies 124 of the shielding structure is in a range between 0.5 µm and 10 µm. In some implementations, a thickness of each of the first body 124a, the second body 124b, the third body 124c, and the fourth body 124d of the bodies 124 of the shielding structure 120 along the Y direction is in a range between 1 nanometer (nm) and 100 nm.

The semiconductor device 100a can include insulation layers 126 that isolate the bodies 124 of the shielding structure 120 with a corresponding contact structure 118. For example, as shown in FIG. 1A, a first insulation layer 126a of the insulation layers 126 is between the first contact structure 118a and the first body 124a. The second insulation layer 126b of the insulation layers 126 is between the second contact structure 118b and the second body 124b. The third insulation layer 126c of the insulation layers 126 is between the third contact structure 118c and the third body 124c. In some implementations, the number of the semiconductor structures 104 stacked on top of each other is more than 3 and the insulation layers 126 further include a fourth insulation layer 126d that is between the fourth contact structure 118d and the fourth body 124d. In some implementations, the first insulation layer 126a, the second insulation layer 126b, the third insulation layer 126c , and the fourth insulation layer 126d include a same dielectric material (e.g., SiO₂). In some implementations, a thickness of each of the insulation layers 126 along a second direction (e.g., the Y direction) perpendicular to the Z direction is in a range between 1 nanometer (nm) and 100nm. In some implementations, as shown in FIG. 1A, the bodies 124 of the shielding structure 120 are not in contact with the conductive layers 116, where an insulation layer 126 of a corresponding body 124 of the shielding structure 120 warps around and surrounds the corresponding body 124 of the shielding structure 120. For example, as shown in FIG. 1A, the second body 124b of the shielding structure 120 does not contact the first conductive layer 116a and the second conductive layer 116b, where the second body 124b is spaced from the first conductive layer 116a and the second conductive layer 116b by the second insulation layer 126b.

In some implementations, the contact structures 118 can be used as a signal transmission channel between the memory devices in each semiconductor structures 104. The bodies 124 of the shielding structure 120 wrap around the signal transmission channel and act as signal shield for the contact structures 118, which reduce the noise and interference generated by the contact structures 118 during a signal transmission process and improve signal integrity during the device operation. The shielding structure 120 can be formed in the dielectric outer layer of the contact structures 118, which reduce the chip area and increase the effective active area ratio of a memory device.

It is understood that the example semiconductor device 100a as shown in FIG. 1A is for illustration purpose and is not intended to be construed in a limiting sense. For example, the semiconductor structures 104 stacked on top of each other is not limited to 4 structures and any number of semiconductor structures 104 can be stacked on top of each other in the semiconductor device 100a. For each semiconductor structures 104, the semiconductor device 100a includes the contact structures 118 that contact the corresponding conductive layer 116 of each of the semiconductor structures 104.

FIG. 1B illustrates a cross-sectional view of an example semiconductor device 100b. The semiconductor device 100b can be similar to the semiconductor device 100a of FIG. 1A, except conductive layers 116 of the semiconductor device 100b have different structures compared to the semiconductor device 100a of FIG. 1A.

The conductive layers 116a - 116d of the semiconductor structures 104a - 104d of the semiconductor device 100b are arranged in a staircase structure. For example, as shown in FIG. 1B, a first end 116b-1 of the first conductive layer 116a, a first end 116b-1 of the second conductive layer 116b, a first end 116c-1 of the third conductive layer 116c, and a first end 116d-1 of the fourth conductive layer 116d are offset along the Y direction; a second end 116a-2 of the first conductive layer 116a, a second end 116b-2 of the second conductive layer 116b, a second end 116c-1 of the third conductive layer 116c, and a second end 116d-2 of the fourth conductive layer 116d are aligned along the Z direction. In some implementations, as shown in FIG. 1B, along the Y direction, a length of the first conductive layer 116a is smaller than a length of the second conductive layer 116b, the length of the second conductive layer 116b is smaller than a length of the third conductive layer 116c, and the length of the third conductive layer 116c is smaller than a length of the fourth conductive layer 116d. In some implementations, the second contact structure 118b and the second body 124b of the shielding structure 120 are between the first end 116a-1 of the first conductive layer 116a and the first end 116b-1 of the second conductive layer 116b along the Y direction, and the third contact structure 118c and the third body 124c of the shielding structure 120 are between the first end 116b-1 of the second conductive layer 116b and the first end 116c-1 of the third conductive layer 116c.

It is understood that the example semiconductor device 100b as shown in FIG. 1B is for illustration purpose and is not intended to be construed in a limiting sense. For example, the semiconductor structures 104 stacked on top of each other is not limited to 4 structures and any number of semiconductor structures 104 can be stacked on top of each other in the semiconductor device 100b. For each semiconductor structures 104, the semiconductor device 100b includes the contact structures 118 that contact the corresponding conductive layer 116 of each of the semiconductor structures 104.

FIG. 1C illustrates a top view of the example semiconductor device 100a along cut line AA’ of FIG. 1A. As shown in FIG. 1C, each of the semiconductor structures 104a - 104d can have multiple contact structures 118 connected to a corresponding conductive layer 116. As shown in FIG. 1C, the contact structures 118 are arranged in a group that has rows extend along the Y direction and columns extend along the X direction. In some implementations, the corresponding conductive layer 116 of each of the semiconductor structures 104a – 104d can be connected to multiple contact structures. For example, as show in FIG. 1C, the contact structures 118 in the first column of the group are coupled to one or more conductive layers in the semiconductor structure 104a, the contact structures 118 in the second column of the group are coupled to one or more conductive layers in the semiconductor structure 104b, the contact structures 118 in the third column of the group are coupled to one or more conductive layers in the semiconductor structure 104c, and the contact structures 118 in the fourth column of the group are coupled to one or more conductive layers in the semiconductor structure 104d. It is understood that the arrangement of the contact structures 118 shown in FIG. 1C is for illustration purpose and is not intended to be construed in a limiting sense, where the contact structures 118 coupled to each of the semiconductor structures 104 are not necessarily in a line and may be arranged in any suitable way (e.g., in an array).

As shown in FIG. 1 C, the base 122 of the shielding structure 120 is isolated from the contact structures 118 by the insulation layer 126 of a corresponding contact structure 118. The contact structures 118 can include a first conductive material including, but not limited to, W, Co, Cu, Al, doped silicon, silicides, or any combination thereof. The base 122 and the bodies 124 of the shielding structure 120 can include a second conductive material including, but not limited to, W, Co, Cu, Al, doped silicon, silicides, or any combination thereof. In some implementations, the first conductive material can be same as the second conductive material. For example, the contact structures 118 and the base 122 and the bodies 124 of the shielding structure 120 can all include W.

FIG. 1D illustrates an enlarged cross-sectional view of the example semiconductor device 100a on zone B of FIG. 1A. The enlarged view shows the contact between a contact structure 118 and the conductive layer 116. The two semiconductor structures 104 are bonded by the bonding structure 106 along the Z direction, where the contact structure 118 extends into one of the two semiconductor structures 104 and contacts the conductive layer 116. The contact structure is surrounded by the body 124 of the shielding structure 120 (e.g., along a direction perpendicular to the first direction), which is connected to ground to provide signal shielding for the contact structure 118. The body 124 is isolated from the contact structure 118 by the insulation layer 126 along the Y direction. The contact structure 118 is connected to the conductive structure 116 along the Z direction at a contact interface 128. The insulation layer 126 warps around the body 124 at the contact interface 128 which isolates the body 124 from the conductive layer 116 along the first direction. For example, as shown in FIG. 1D, the contact structure 118 and the insulating layer 126 are in contact with the conductive layer 116 along the Z direction, and the body 124 of the shielding structure 120 surrounds the contact structure 118 (e.g., along a direction perpendicular to the first direction) without contacting the conductive layer 116. By isolating the body 124 of the shielding structure 120 from the conductive layer 116, the contact structure 118 can be used as a signal transmission channel that transmits signal to the DRAM die, where the body 124 of the shielding structure 120 can be connected to ground and used as a signal shield to reduce noise during the signal transmission process.

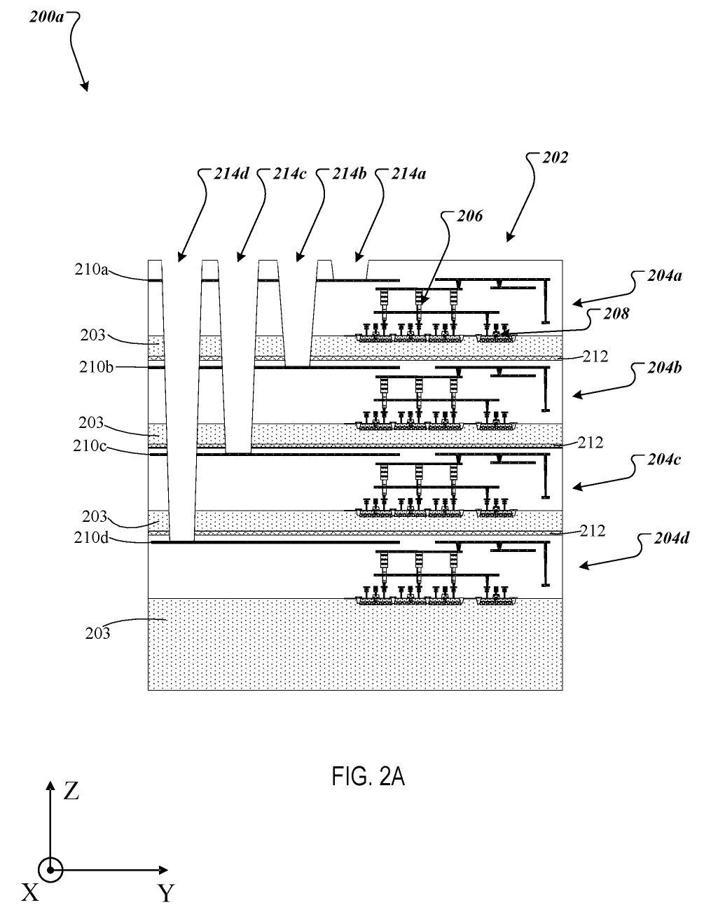

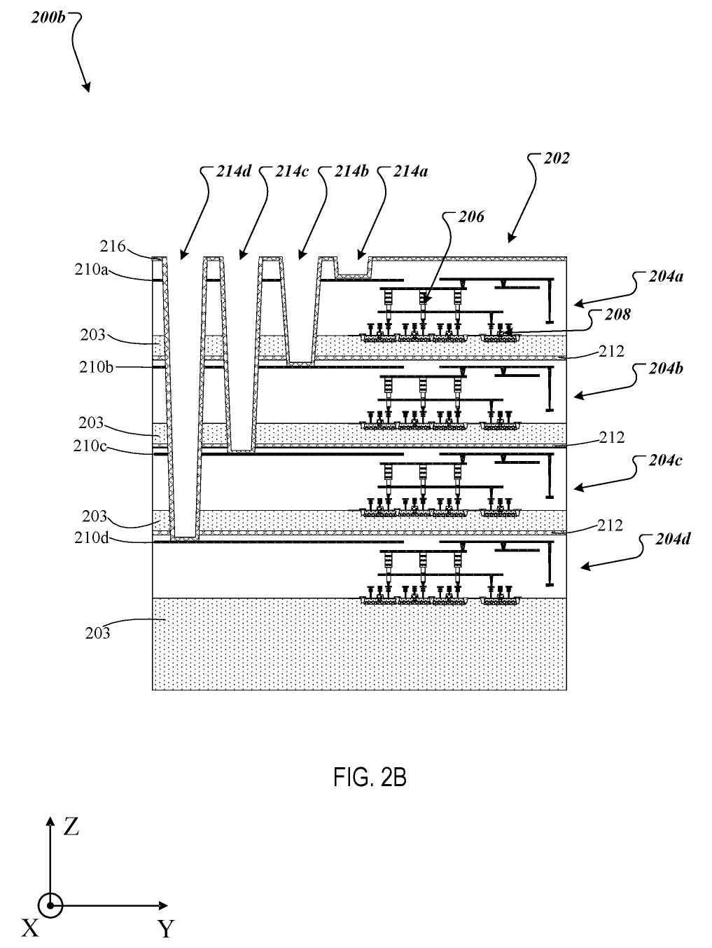

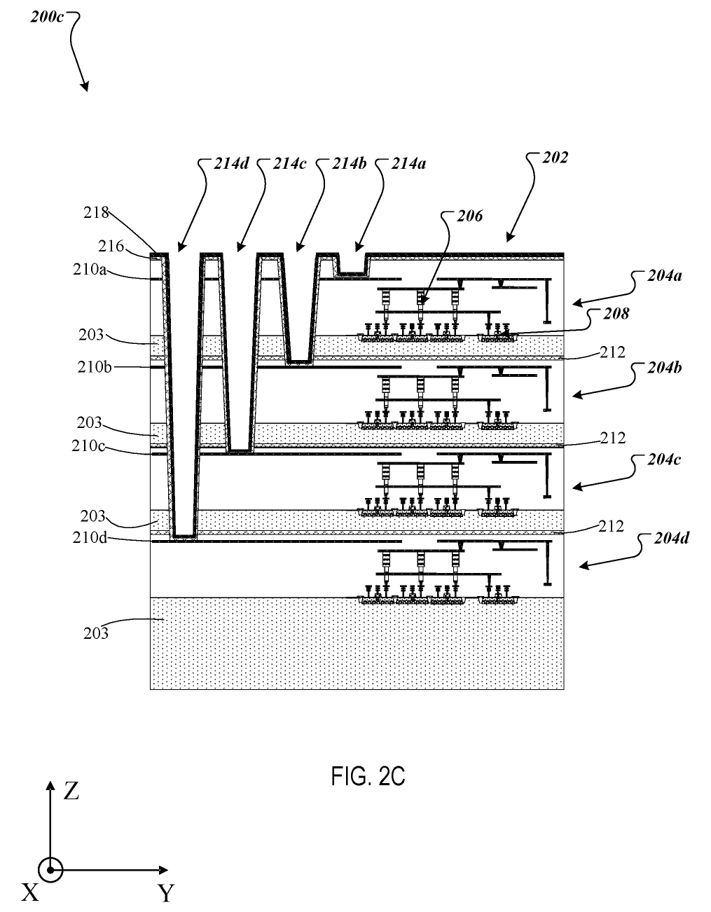

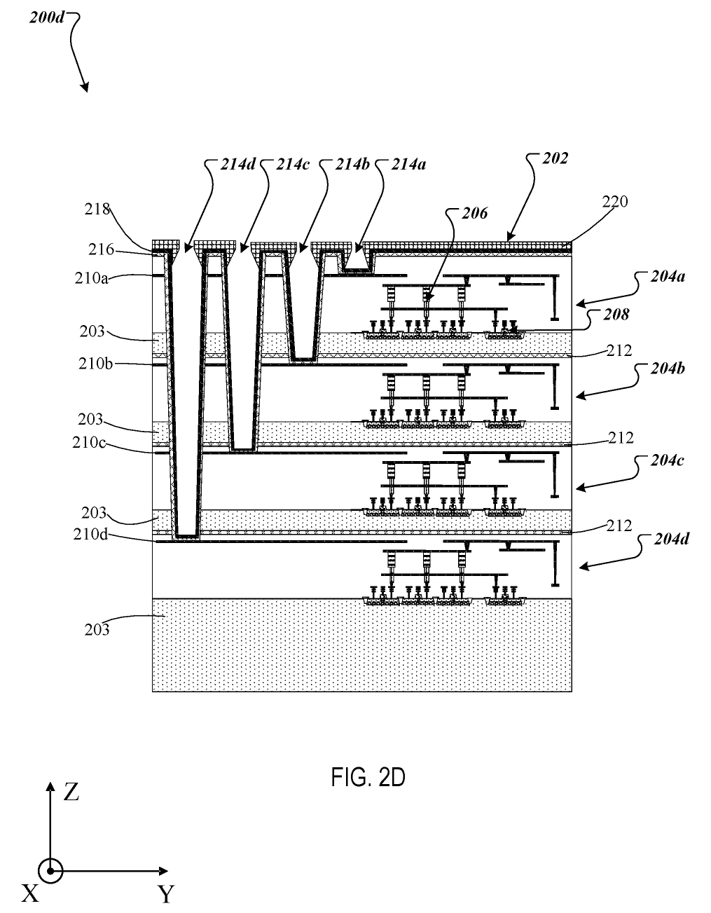

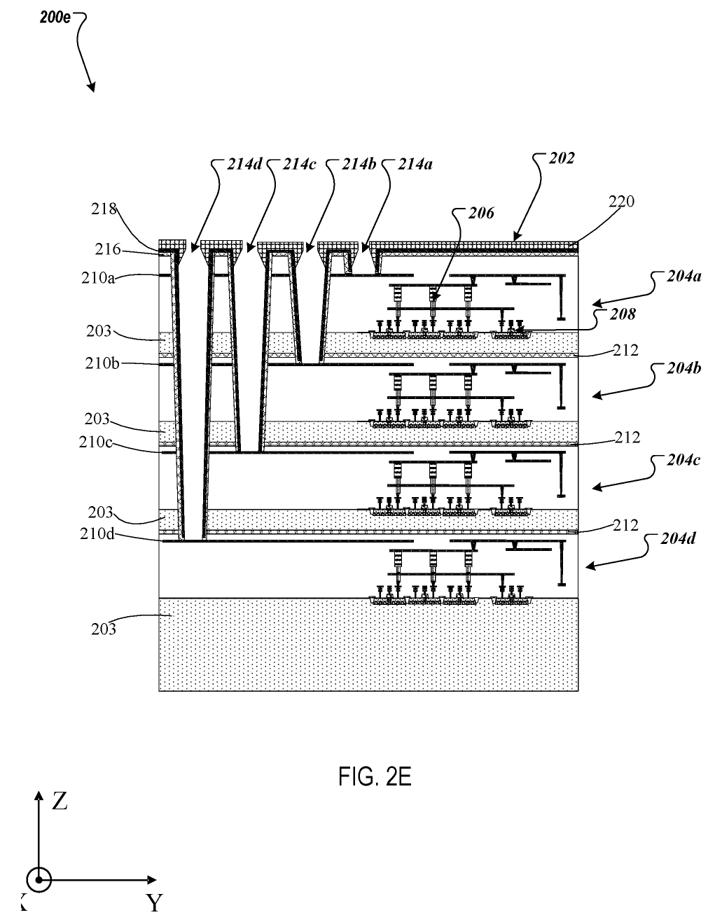

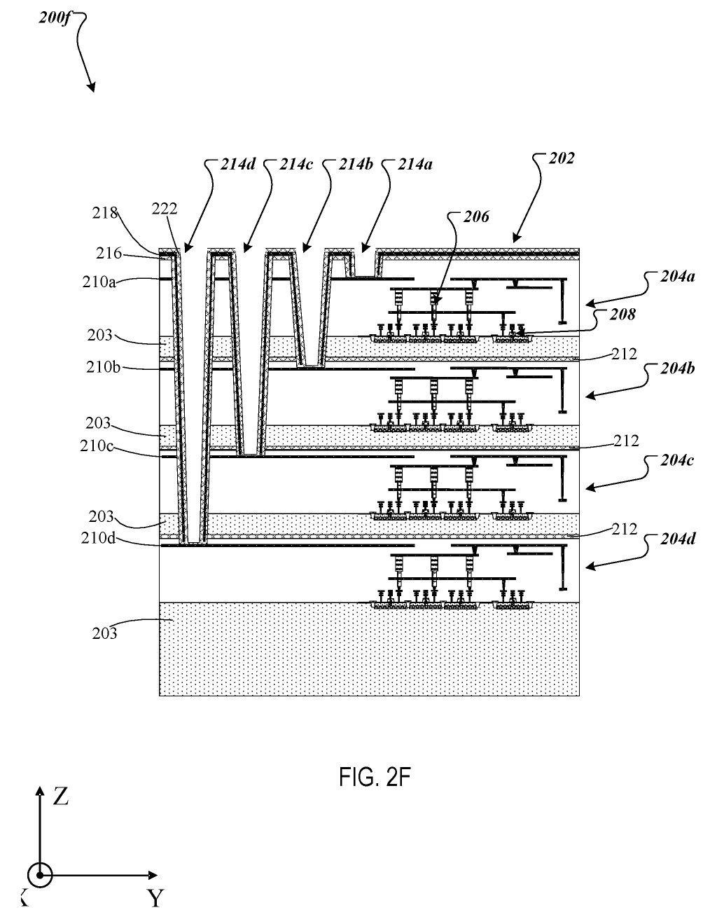

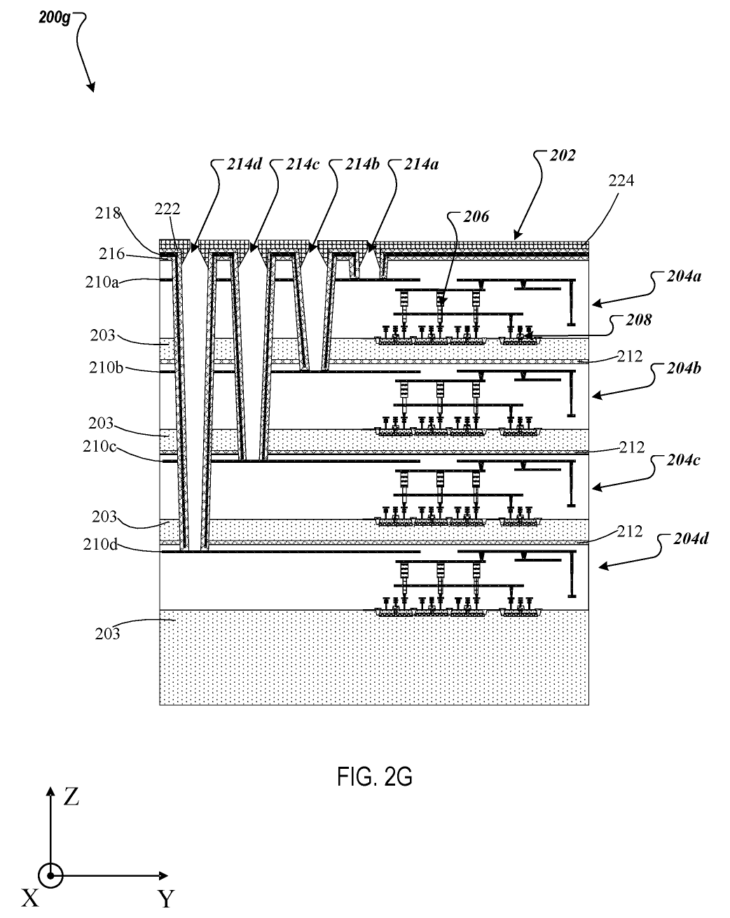

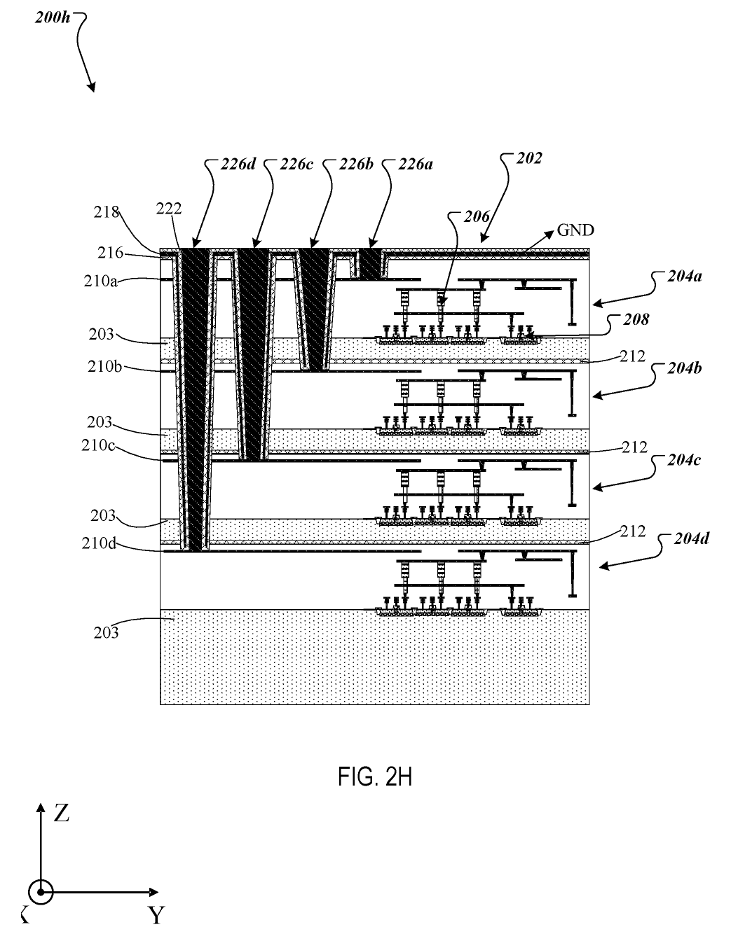

FIGS. 2A - 2H illustrate an example process of fabricating a semiconductor device, such as the semiconductor device 100a as illustrated in FIG. 1A. FIGS. 2A - 2H show cross sectional views of example semiconductor structures at various stages of the fabrication process.

FIG. 2A illustrates a semiconductor structure 200a. The semiconductor structure 200a includes a stack 202 of semiconductor structures 204a - 204d stacked on top of each other along a vertical direction (e.g., the Z direction). Each of the semiconductor structures 204a - 204d can be a dynamic random-access memory (DRAM) die with memory cell arrays 206 and peripherical circuit 208. In some implementations, the memory array 206 can include an array of memory cells (e.g., DRAM cells). The memory cells of the memory array 206 are coupled to the peripherical circuit 208. Each of the semiconductor structures 204a - 204d can include a substrate 203, which can be thinned down during the fabrication process. For example, as shown in FIG. 2A, the substrate 203 of the semiconductor structure 204a is thinned down. In some implementations, the substrate 203 of some semiconductor structure (e.g., semiconductor structure 204d as shown in FIG. 2A) can be thicker than that of other semiconductor structures to provide support for the stack 202. As shown in FIG. 2A, the semiconductor structures 204a - 204d can also include conductive layers 210a - 210d. The conductive layers 210a - 210d of the semiconductor structures 204a - 204b are aligned along the Z direction. The semiconductor structures 204a - 204d are bonded by a bonding structure 212. The semiconductor structure 200a can include contact holes 214a - 214d , which can be formed by etching a portion of the semiconductor structures 204a - 204d. The contact hole 214a extends into the semiconductor structure 204a and contacts the conductive layer 210a. The contact hole 214b extends through the semiconductor structure 204a and into the semiconductor structure 204b and contacts the conductive layer 210b. The contact hole 214c extends through the semiconductor structures 204a - 204b and into the semiconductor structure 204c and contacts the conductive layer 210c. The contact hole 214d extends through the semiconductor structures 204a - 204c and into the semiconductor structure 204d and contacts the conductive layer 210d. In some implementations, as shown in FIG. 2A, the contact hole 214b extends through the conductive layer 210a, the contact hole 214c extends through the conductive layers 210a - 210b , and the contact hole 214d extends through the conductive layers 210a - 210c along the first direction.

FIG. 2B illustrates a semiconductor structure 200b, which can be formed by depositing a dielectric material on side walls of the contact holes 214a - 214d and a top surface of the semiconductor structure 204a to form a first dielectric layer 216.

FIG. 2C illustrates a semiconductor structure 200c, which can be formed by depositing a conductive material on the first dielectric layer 216 to form a first metal layer 218. As shown in FIG. 2C, the first metal layer 218 is isolated from the conductive layers 210a - 210d by the first dielectric layer 216 along a horizontal direction (e.g., the Y direction) perpendicular to the Z direction.

FIG. 2D illustrates a semiconductor structure 200d, which can be formed by depositing a mask material on a portion of the first metal layer 218 to form a first hard mask layer 220. The first hard mask layer 220 covers the top surface of the semiconductor structure 204a and a portion (e.g., side walls) of the contact holes 214a- 214d and exposes a bottom of each of the contact holes 214a - 214d .

FIG. 2E illustrates a semiconductor structure 200e, which can be formed by etching through the first dielectric layer 216 and the first metal layer 218 on the bottom of the contact holes 214a - 214d to expose a corresponding conductive layers 210a- 210d of the semiconductor structures 204a - 204d. For example, as shown in FIG. 2E, the first dielectric layer 216 and the first metal layer 218 on the bottom of the contact hole 214a is etched to expose the conductive layer 210a of the semiconductor structure 204a; the first dielectric layer 216 and the first metal layer 218 on the bottom of the contact hole 214b is etched to expose the conductive layer 210b of the semiconductor structure 204b; the first dielectric layer 216 and the first metal layer 218 on the bottom of the contact hole 214c is etched to expose the conductive layer 210c of the semiconductor structure 204c; and the first dielectric layer 216 and the first metal layer 218 on the bottom of the contact hole 214d is etched to expose the conductive layer 210d of the semiconductor structure 204d.

FIG. 2F illustrates a semiconductor structure 200f, which can be formed by removing the first hard mask layer 220. The semiconductor structure 200f can also include a second dielectric layer 222. The second dielectric layer 222 can be formed by depositing a dielectric material on the side walls of the contact holes 214a - 214d and a surface of the semiconductor structure 204a. In some implementations, the dielectric material of the first dielectric layer 216 can be similar to the dielectric material of the second dielectric layer 222. For example, the first dielectric layer 216 and the second dielectric layer 222 can both include silicon oxide. In some implementation, as shown in FIG. 2F, the first dielectric layer 216 and the second dielectric layer 222 are connected at the bottom of the contact holes 214a - 214d and surrounded the first metal layer 218 to isolate the first metal layer 218 from the conductive layers 210a - 210d.

FIG. 2G illustrates a semiconductor structure 200g, which can be formed by depositing a mask material on a portion of the second dielectric layer 222 to form a second hard mask layer 224. The second hard mask layer 224 covers a portion of the contact holes 214a - 214d and exposes a bottom of the contact holes 214a - 214d. The conductive layers 210a - 210b at the bottom of the contact holes 214a - 214d are exposed by etching the second dielectric layer 222 on the bottom of the contact holes 214a - 214d. The second hard mask layer 224 is used as a protective layer for a remaining portion of the second dielectric layer 222 during the etching process to expose the conductive layers 210a - 210b at the bottom of the contact holes 214a - 214d. In some implementations, as shown in FIG. 2G, the first metal layer 218 is surrounded by the first dielectric layer 216 and the second dielectric layer 222 and isolated from the conductive layers 210a - 210d.

FIG. 2H illustrates a semiconductor structure 200h, which can be formed by removing the second hard mask layer 224. The semiconductor structure 200h also includes contact structures 226a - 226d. The contact structures 226a - 226d can be formed by filling a conductive material in the contact holes 214a - 214d. The contact structures 226a - 226d are connected to a corresponding conductive layers 210a - 210d of the semiconductor structures 204a - 204d. For example, the contact structure 226a is connected to the conductive layer 210a; the contact structure 226b is connected to the conductive layer 210b; the contact structure 226c is connected to the conductive layer 210c; and the contact structure 226d is connected to the conductive layer 210d. The contact structures 226a - 226d are isolated from the first metal layer 218 by the second dielectric layer 222. In some implementations, the contact structures 226a - 226d can be used as signal transmission channels between the memory cell arrays 206 in each of the semiconductor structures 204a - 204d and the first metal layer 222 is connected to ground and can be used as a ground shield for the signal transmission channels.

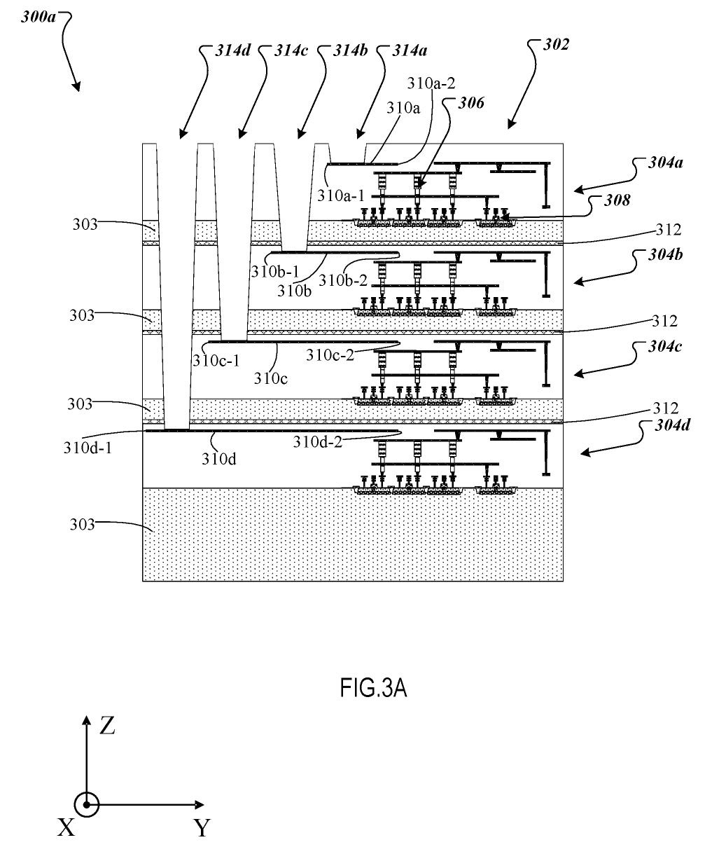

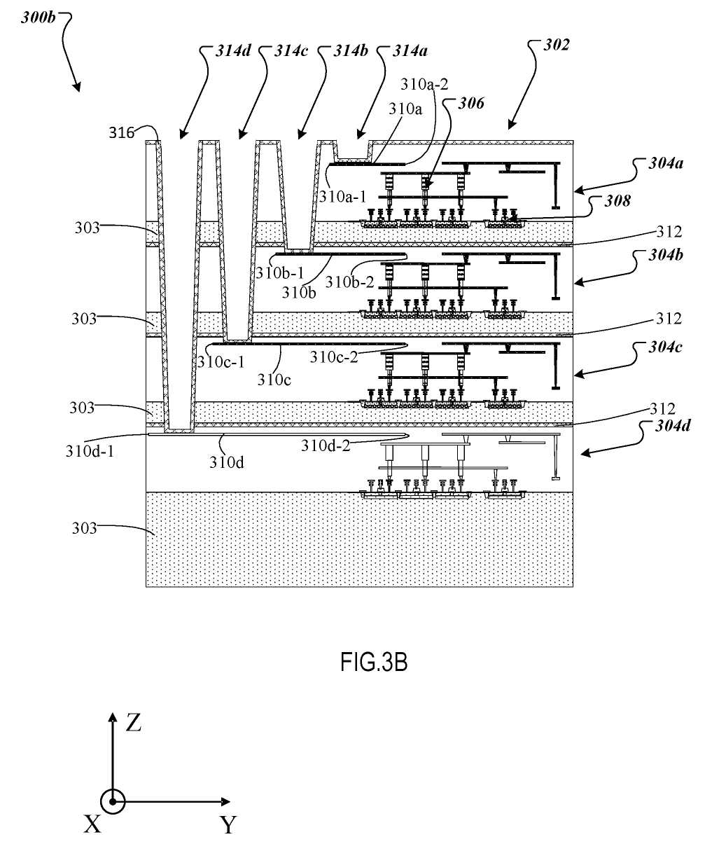

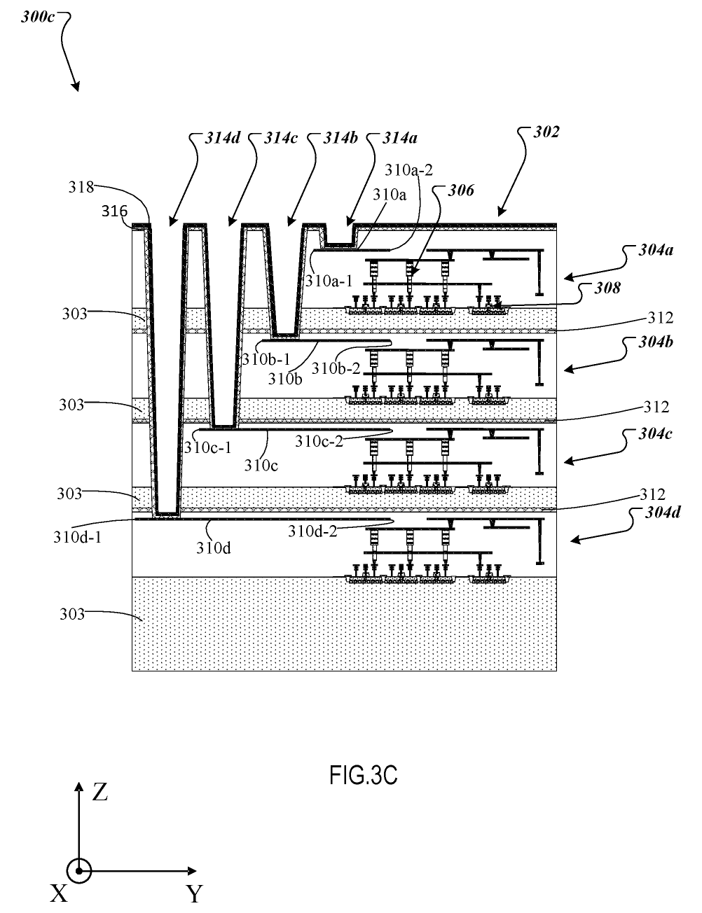

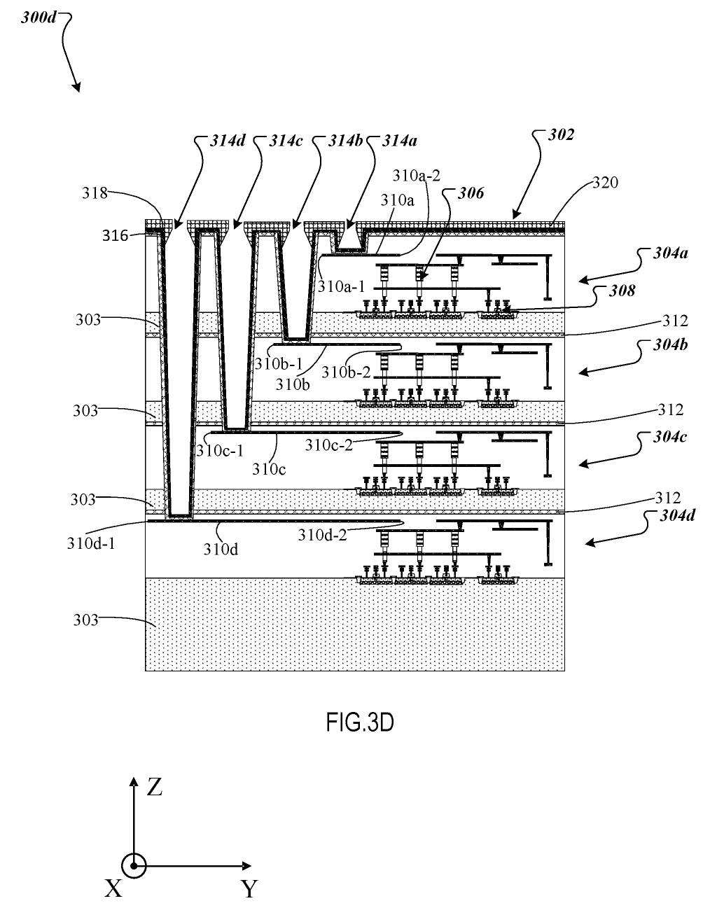

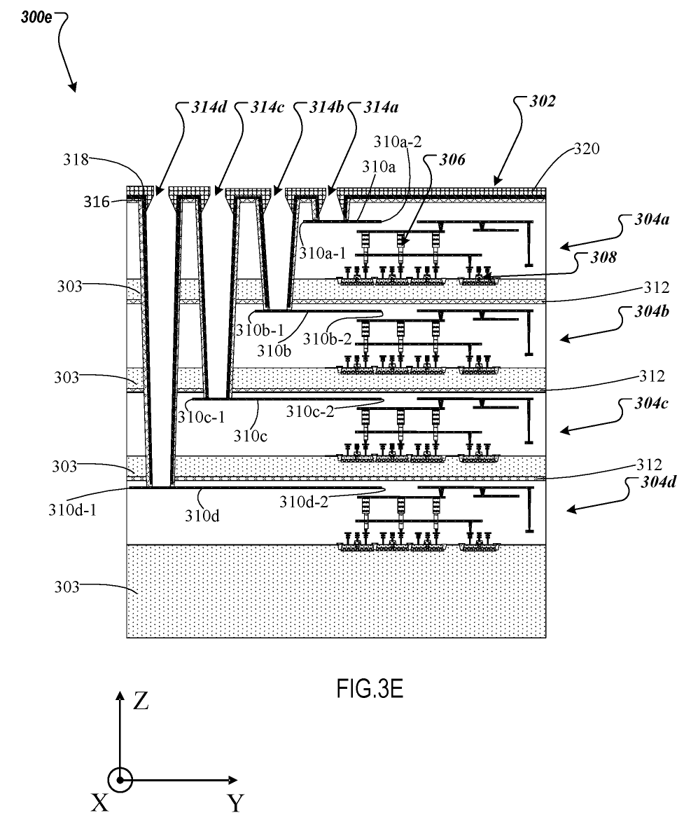

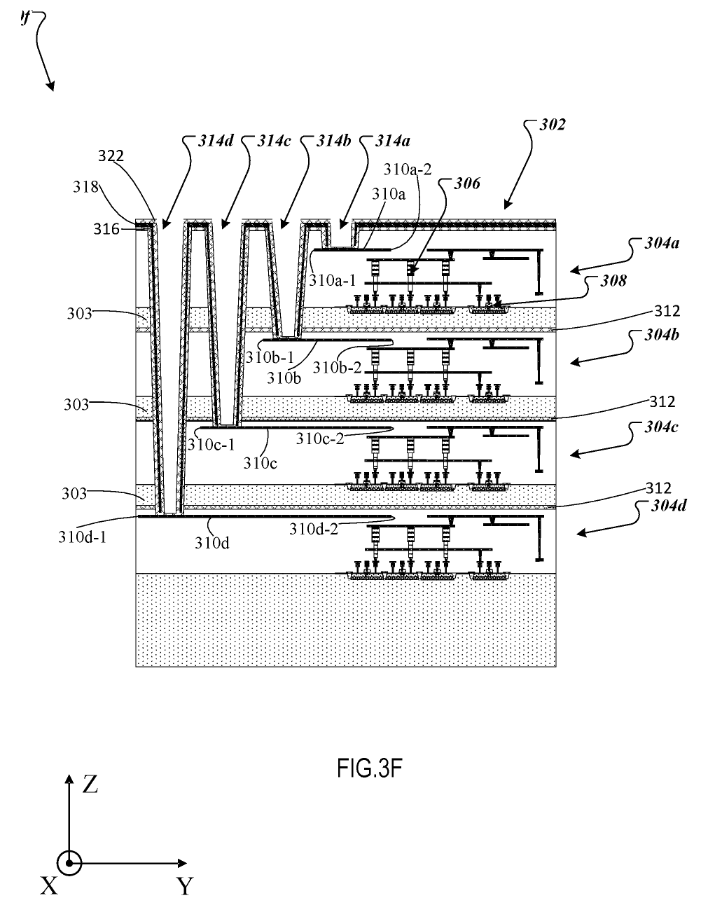

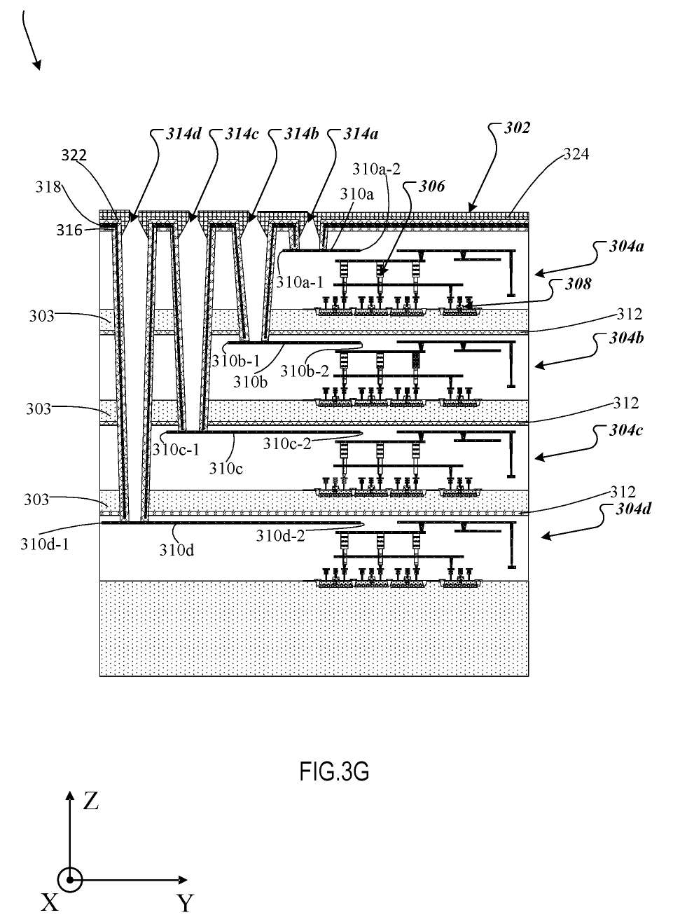

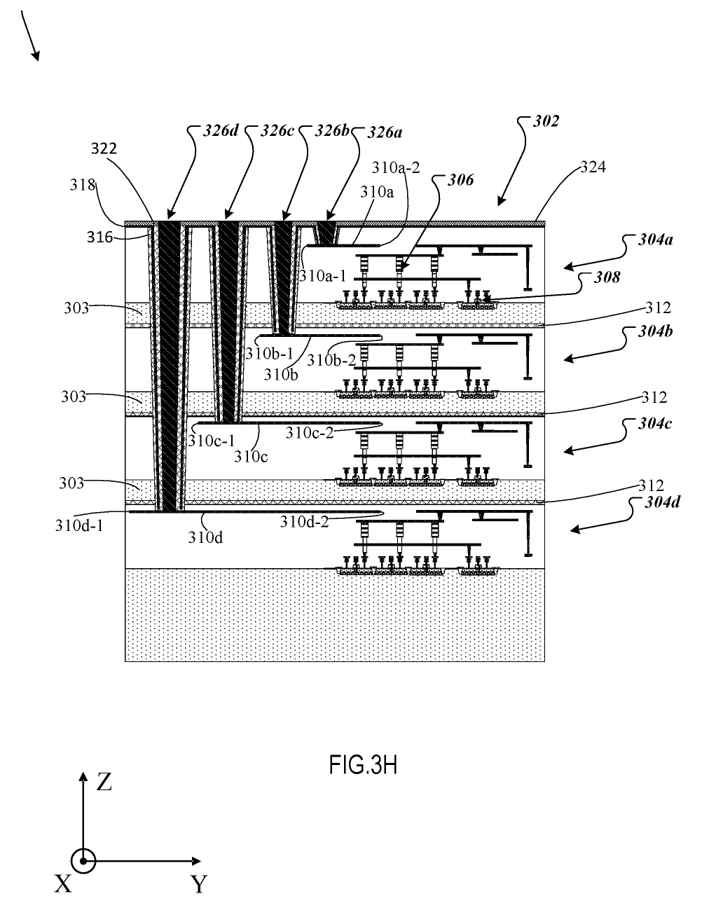

FIGS. 3A - 3H illustrate an example process of fabricating a semiconductor device, such as the semiconductor device 100a as illustrated in FIG. 3A. FIGS. 3A - 3H show cross sectional views of example semiconductor structures at various stages of the fabrication process.

FIG. 3A illustrates a semiconductor structure 300a. The semiconductor structure 300a includes a stack 302 of semiconductor structures 304a - 304d stacked on top of each other along a vertical direction (e.g., the Z direction). Each of the semiconductor structures 304a - 304d can be a dynamic random-access memory (DRAM) die with memory cell arrays 306 and peripherical circuit 308. In some implementations, the memory array 306 can include an array of memory cells (e.g., DRAM cells). The memory cells of the memory array 306 are coupled to the peripherical circuit 308. Each of the semiconductor structures 304a - 304d can include a substrate 303, which can be thinned down during the fabrication process. For example, as shown in FIG. 3A, the substrate 303 of the semiconductor structure 304a is thinned down. In some implementations, the substrate 303 of some semiconductor structure (e.g., semiconductor structure 304d as shown in FIG. 3A) can be thicker than that of other semiconductor structures to provide support for the stack 302. As shown in FIG. 3A, the semiconductor structures 304a - 304b can also include conductive layers 310a- 310d. The conductive layers 310a- 310d of the semiconductor structures 304a - 304b are arranged in a staircase structure. For example, as shown in FIG. 3A, first ends 310a -1 - 310d-1 of the conductive layers 310a- 310d are offset along a horizontal direction (e.g., the Y direction) perpendicular to the Z direction; second ends 310a -2 - 310d-2 of the conductive layers 310a- 310d are aligned along the Z direction. In some implementations, as shown in FIG. 3A, along the Y direction, a length of the conductive layer 310a is smaller than a length of the conductive layer 310b, the length of the conductive layer 310b is smaller than a length of the conductive layer 310c, and the length of the conductive layer 310c is smaller than a length of the conductive layer 310d. The semiconductor structures 304a - 304b are bonded by a bonding structure 312. The semiconductor structure 300a can include contact holes 314a - 314d, which can be formed by etching a portion of the semiconductor structures 304a - 304d. The contact hole 314a extends into the semiconductor structure 304a and contacts the conductive layer 310a. The contact hole 314b extends through the semiconductor structure 304a and into the semiconductor structure 304b and contacts the conductive layer 310b without contacting the conductive layer 310a. The contact hole 314c extends through the semiconductor structures 304a - 304b and into the semiconductor structure 304c and contacts the conductive layer 310c without contacting the conductive layers 310a- 310b. The contact hole 314d extends through the semiconductor structures 304a - 304c and into the semiconductor structure 304d and contacts the conductive layer 310d without contacts the conductive layers 310a - 310c. In some implementations, as shown in FIG. 3A, the contact hole 314b is between the first ends 310a-1 - 310b-1 along the Y direction and the contact hole 314c is between the first ends 310b-1 - 310c - 1 along the Y direction.

FIG. 3B illustrates a semiconductor structure 300b, which can be formed by depositing a dielectric material on side walls of the contact holes 314a - 314d and a top surface of the semiconductor structure 304a to form a first dielectric layer 316.

FIG. 3C illustrates a semiconductor structure 300c, which can be formed by depositing a conductive material on the first dielectric layer 316 to form a first metal layer 318. As shown in FIG. 3C, the first metal layer 318 is isolated from the conductive layers 310a - 310d by the first dielectric layer 316 along the Z direction.

FIG. 3D illustrates a semiconductor structure 300d, which can be formed by depositing a mask material on a portion of the first metal layer 318 to form a first hard mask layer 320. The first hard mask layer 320 covers the top surface of the semiconductor structure 304a and a portion (e.g., side walls) of the contact holes 314a - 314d and exposes a bottom of each of the contact holes 314a - 314d.

FIG. 3E illustrates a semiconductor structure 300e, which can be formed by etching through the first dielectric layer 316 and the first metal layer 318 on the bottom of the contact holes 314a - 314d to expose a corresponding conductive layers 310a - 310d of the semiconductor structures 304a- 304d. For example, as shown in FIG. 3E, the first dielectric layer 316 and the first metal layer 318 on the bottom of the contact hole 314a is etched to expose the conductive layer 310a of the semiconductor structure 304a; the first dielectric layer 316 and the first metal layer 318 on the bottom of the contact hole 314b is etched to expose the conductive layer 310b of the semiconductor structure 304b; the first dielectric layer 316 and the first metal layer 318 on the bottom of the contact hole 314c is etched to expose the conductive layer 310c of the semiconductor structure 304c; and the first dielectric layer 316 and the first metal layer 318 on the bottom of the contact hole 314d is etched to expose the conductive layer 310d of the semiconductor structure 304d.

FIG. 3F illustrates a semiconductor structure 300f, which can be formed by removing the first hard mask layer 320. The semiconductor structure 300f can also include a second dielectric layer 322. The second dielectric layer 322 can be formed by depositing a dielectric material on the side walls of the contact holes 314a - 314d and a surface of the semiconductor structure 304a. In some implementations, the dielectric material of the first dielectric layer 316 can be similar to the dielectric material of the second dielectric layer 322. For example, the first dielectric layer 316 and the second dielectric layer 322 can both include silicon oxide. In some implementation, as shown in FIG. 3F, the first dielectric layer 316 and the second dielectric layer 322 are connected at the bottom of the contact holes 314a - 314d and surrounded the first metal layer 318 to isolate the first metal layer 318 from the conductive layers 310a - 310d.

FIG. 3G illustrates a semiconductor structure 300g, which can be formed by depositing a mask material on a portion of the second dielectric layer 322 to form a second hard mask layer 324. The second hard mask layer 324 covers a portion of the contact holes 314a - 314d and exposes a bottom of the contact holes 314a - 314d. The conductive layers 310a - 310b at the bottom of the contact holes 314a - 314d are exposed by etching the second dielectric layer 322 on the bottom of the contact holes 314a - 314d. The second hard mask layer 324 is used as a protective layer for a remaining portion of the second dielectric layer 322 during the etching process to expose the conductive layers 310a - 310b at the bottom of the contact holes 314a - 314d. In some implementations, as shown in FIG. 3G, the first metal layer 318 is surrounded by the first dielectric layer 316 and the second dielectric layer 322 and isolated from the conductive layers 310a - 310d at the bottom of the contact holes 314a - 314d.

FIG. 3H illustrates a semiconductor structure 300h, which can be formed by removing the second hard mask layer 324. The semiconductor structure 300h also includes contact structures 326a - 326d. The contact structures 326a - 326d can be formed by filling a conductive material in the contact holes 314a - 314d. The contact structures 326a - 326d are connected to a corresponding conductive layers 310a - 310d of the semiconductor structures 304a - 304d. For example, the contact structure 326a is connected to the conductive layer 310a; the contact structure 326b is connected to the conductive layer 310b; the contact structure 326c is connected to the conductive layer 310c; and the contact structure 326d is connected to the conductive layer 310d. The contact structures 326a - 326d are isolated from the first metal layer 318 by the second dielectric layer 322. In some implementations, the contact structures 326a - 326d can be used as signal transmission channels between the memory cell arrays 306 in each of the semiconductor structures 304a - 304d and the first metal layer 322 is connected to ground and can be used as a ground shield for the signal transmission channels.

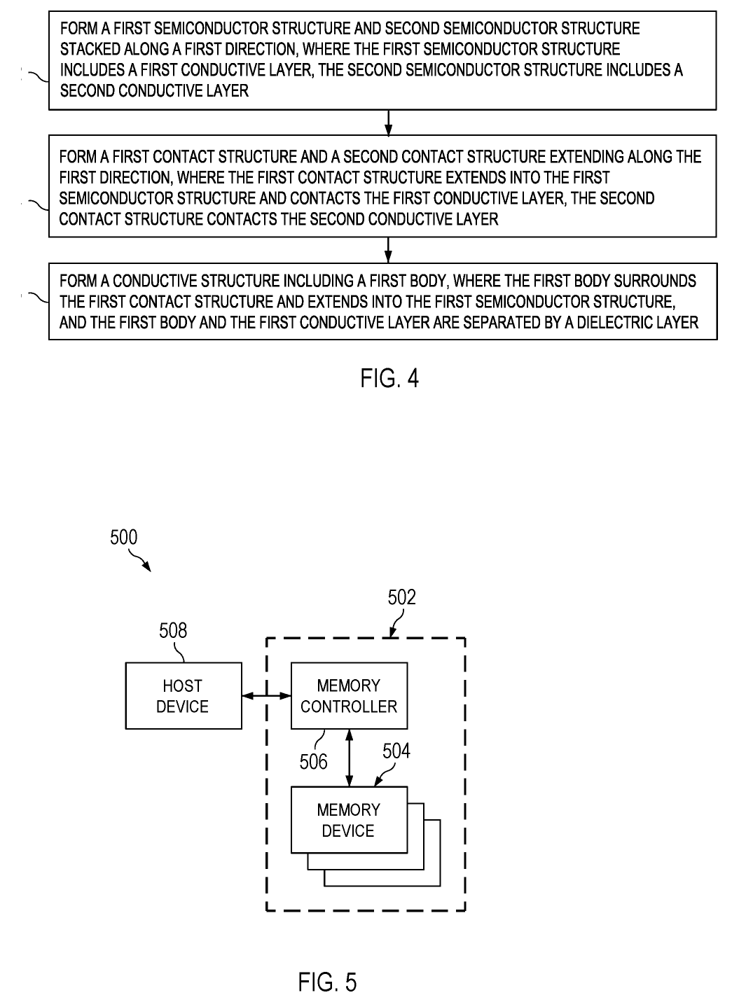

FIG. 4 illustrates a flow chart of an example process 400 of manufacturing a semiconductor structure. The process 400 can be performed to form a semiconductor device (e.g., the semiconductor device 100a of FIG. 1A and the semiconductor device 100b of FIG. 1B). The process 400 can be described in view of FIGS. 2A - 2H or FIGS. 3A - 3H. The process 400 can include one or more steps of the fabrication process of forming the semiconductor structures in FIGS. 2A - 2H or FIGS. 3A - 3H. It is understood that the operations shown in process 400 are not exhaustive and that other operations can be performed as well before, after, or between any of the illustrated operations. Further, some of the operations may be performed simultaneously, or in a different order than shown in FIG. 4.

At operation 402, a first semiconductor structure (e.g., the semiconductor structure 104a of FIG. 1A) and second semiconductor structure (e.g., the semiconductor structure 104b of FIG. 1A) stacked along a first direction (e.g., the Z direction) are formed, where the first semiconductor structure includes a first conductive layer (e.g., the first conductive layer 116a of FIG. 1A), the second semiconductor structure includes a second conductive layer (e.g., the second conductive layer 116b of FIG. 1A).

At operation 404, a first contact structure (e.g., the first contact structure 118a of FIG. 1A) and a second contact structure (e.g., the second contact structure 118b of FIG. 1A) extending along the first direction are formed, where the first contact structure extends into the first semiconductor structure and contacts the first conductive layer, the second contact structure extends through the first bonding structure and contacts the second conductive layer.

At operation 406, a shielding structure or a conductive structure (e.g., the shielding structure 120 of FIG. 1A) including a first body (e.g., the first body 124a of FIG. 1A), where the first body surrounds the first contact structure (e.g., along a direction perpendicular to the first direction) and extends into the first semiconductor structure. The first body and the first conductive layer can be separated by a dielectric layer.

In some implementations, the shielding structure further include a base (e.g., the base 122 of FIG. 1A) and a second body (e.g., the second body 124b of FIG. 1A). The base can be perpendicular to the first direction. The first body can contact the base, and the second body surrounds the second contact structure and contacts the base. A dielectric material is between the second body and the second conductive layer, and between the second body and the first conductive layer.

In some implementations, the method further includes forming a first bonding structure (e.g., the bonding structure 106a of FIG. 1A) between the first semiconductor structure and the second semiconductor structure along the first direction. The first semiconductor structure and the second semiconductor structure are bonded through the first bonding structure. The method further includes forming a first contact hole (e.g., the contact hole 214a of FIG. 2A and the contact hole 314a of FIG. 3A) and a second contact hole (e.g., the contact hole 214b of FIG. 2A and the contact hole 314b of FIG. 3A) extending along the first direction, where the first contact hole extends into the first semiconductor structure and reaches the first conductive layer, and the second contact hole extends through the first bonding structure and reaches the second conductive layer; and forming a first dielectric layer (e.g., the first dielectric layer 216 of FIG. 2B or the first dielectric layer 316 of FIG. 3B) by depositing a dielectric material on top of the first semiconductor structure and in the first contact hole and the second contact hole.

In some implementations, the first conductive layer is aligned with the second conductive layer along the first direction; the second contact hole extends through the first conductive layer; and forming the first contact hole and the second contact hole includes forming the first contact hole and a first portion of the second contact hole by a first etching process, where the first contact hole and the first portion of the second contact hole both reach the first conductive layer; filling the first contact hole and the first portion of the second contact hole with a filler material; forming a mask on top of the first semiconductor structure, where the mask covers an opening of the first contact hole and includes a pattern that matches an opening of the second contact hole; removing the filler material in the first portion of the second contact hole; forming the second contact hole by a second etching process, where the second contact hole reaches the second conductive layer; and removing the mask and the filler material in the first contact hole.

In some implementations, a first end (e.g., the first end 310a-1 of FIG. 3A) of the first conductive layer and a first end (e.g., the first end 310b-1 of FIG. 3B) of the second conductive layer are offset along a second direction (e.g., the Y direction) perpendicular to the first direction; the second contact hole is between the first end of the first conductive layer and the first end of the second conductive layer along the second direction; the second contact hole does not extend through the first conductive layer; and forming the first contact hole and the second contact hole includes forming the first contact hole and the second contact hole by a same etching process.

In some implementations, forming the shielding structure includes forming a conductive structure (e.g., the first metal layer 218 of FIG. 2C or the first metal layer 318 of FIG. 3C) by depositing a conductive material on top of the first dielectric layer; and etching off a bottom portion of the conductive structure and the first dielectric layer in the first contact hole and a bottom portion of the conductive structure and the first dielectric layer in the second contact hole by a third etching process, where the third etching process exposes the first conductive layer in the first contact hole and exposes the second conductive layer in the second contact hole, where the first body of the shielding structure is formed by the conductive structure in the first contact hole, the second body of the shielding structure is formed by the conductive structure in the second contact hole, and the base of the shielding structure is formed by a remaining portion of the conductive structure on top of the first semiconductor structure.

In some implementations, the method further includes forming a second dielectric layer (e.g., the second dielectric layer 222 of FIG. 2F or the second dielectric layer 322 of FIG. 3F) by depositing the dielectric material on top of the first semiconductor structure and in the first contact hole and the second contact hole; and etching off a bottom portion of the second dielectric layer in the first contact hole and a bottom portion of the second dielectric layer in the second contact hole by a fourth etching process, where the fourth etching process exposes the first conductive layer in the first contact hole and exposes the second conductive layer in the second contact hole.

In some implementations, forming the first contact structure and the second contact structure includes depositing the conductive material in the first contact hole and the second contact hole, where the first contact structure is formed by the conductive material in the first contact hole, and the second contact structure is formed by the conductive material in the second contact hole.

FIG. 5 illustrates a block diagram of a system 500 having one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 5, the system 500 can include a host device 508 and a memory system 502 having one or more 3D memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more 3D memory devices 504.

A 3D memory device 504 can be any 3D memory device disclosed herein, such as a 3D memory device depicted in FIGS. 1A - 1B. In some implementations, a 3D memory device 504 includes a DRAM memory. Memory controller 506 (a.k.a., a controller circuit) is coupled to 3D memory device 504 and host device 508. Consistent with implementations of the present disclosure, 3D memory device 504 can include a plurality of conductive interconnections through a cover layer that are in contact with conductive pads in a conductive pad layer, and memory controller 506 can be coupled to 3D memory device 504 through at least one of the plurality of conductive interconnections. Memory controller 506 is configured to control 3D memory device 504. For example, memory controller 506 may be configured to operate a plurality of channel structures via word lines. Memory controller 506 can manage data stored in 3D memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of 3D memory device 504, such as read, erase, and program (or write) operations. Memory controller 506 can also be configured to manage various functions with respect to the data stored or to be stored in 3D memory device 504 including, but not limited to bad-block management, garbage collection, logical-to-physical address conversion, wear leveling, etc. In some implementations, memory controller 506 is further configured to process error correction codes (ECCs) with respect to the data read from or written to 3D memory device 504. Any other suitable functions may be performed by memory controller 506 as well, for example, formatting 3D memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more 3D memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single 3D memory device 504 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature’s relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+-.10%, .+-.20%, or .+-.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
multiple semiconductor structures stacked along a first direction, wherein the multiple semiconductor structures comprise a first semiconductor structure comprising a first conductive layer and a second semiconductor structure comprising a second conductive layer;
multiple contact structures extending along the first direction, wherein the multiple contact structures comprise a first contact structure and a second contact structure, the first contact structure extends into the first semiconductor structure and contacts the first conductive layer, the second contact structure contacts the second conductive layer; and
a conductive structure comprising a first body, wherein the first body surrounds the first contact structure and extends into the first semiconductor structure along the first direction, and the first body and the first conductive layer are separated by a dielectric layer.

2. The semiconductor device of claim 1, wherein the conductive structure comprises a conductive material and is configured to be coupled to a lower level voltage.

3. The semiconductor device of claim 1, further comprising a first insulation layer between the first contact structure and the first body and a second insulation layer between the second contact structure and the second body, wherein the first insulation layer and the second insulation layer comprise a same dielectric material.

4. The semiconductor device of claim 3, wherein a thickness of each of the first insulation layer and the second insulation layer along a second direction perpendicular to the first direction is in a range between 1 nanometer (nm) and 100 nm.

5. The semiconductor device of claim 1, wherein the conductive structure further comprises a base and a second body, the base is perpendicular to the first direction, the first body and the second body contact the base, the second body surrounds the second contact structure and extends through the first conductive layer along the first direction, and a dielectric material is between the second body and the second conductive layer, and between the second body and the first conductive layer.

6. The semiconductor device of claim 1, further comprising:
one or more bonding structures comprising a first bonding structure between the first semiconductor structure and the second semiconductor structure, wherein:
the first semiconductor structure and the second semiconductor structure are bonded through the first bonding structure, and the first bonding structure comprises a dielectric material;
the second contact structure extends through the first bonding structure along the first direction; and
the second body extends through the first bonding structure along the first direction.

7. The semiconductor device of claim 1, wherein the first conductive layer is aligned with the second conductive layer along the first direction, the first conductive layer is comprised in an interconnect layer of the first semiconductor structure, and the second conductive layer is comprised in an interconnect layer of the second semiconductor structure.

8. The semiconductor device of claim 1, wherein:
the multiple semiconductor structures further comprise a third semiconductor structure, wherein the first semiconductor structure, the second semiconductor structure, and the third semiconductor structure are stacked along the first direction, and the third semiconductor structure comprises a third conductive layer;
the one or more bonding structures further comprise a second bonding structure between the second semiconductor structure and the third semiconductor structure, wherein the second semiconductor structure and the third semiconductor structure are bonded through the second bonding structure;
the multiple contact structures further comprise a third contact structure, wherein the third contact structure extends through the first conductive layer, the second conductive layer, the first bonding structure, and the second bonding structure and contacts the third conductive layer; and
the conductive structure further comprises a third body extending along the first direction, wherein the third body surrounds the third contact structure, extends through the first conductive layer, the second conductive layer, the first bonding structure, and the second bonding structure, and contacts the base without contacting the first conductive layer, the second conductive layer, and the third conductive layer.

9. The semiconductor device of claim 1, wherein the at least one of the first semiconductor structure or the second semiconductor structure is a dynamic random-access memory (DRAM) device.

10. The semiconductor device of claim 9, wherein the DRAM device comprises an array structure and a peripheral structure, the array structure comprises an array of DRAM cells, at least one DRAM cell of the array structure comprises a transistor and a capacitor, and the peripheral structure comprises a peripheral circuit configured to control the array of DRAM cells.

11. A semiconductor device, comprising:
multiple semiconductor structures stacked along a first direction, wherein the multiple semiconductor structures comprise a first semiconductor structure comprising a first conductive layer and a second semiconductor structure comprising a second conductive layer;
multiple contact structures extending along the first direction, wherein the multiple contact structures comprise a first contact structure and a second contact structure, the first contact structure extends into the first semiconductor structure and contacts the first conductive layer, the second contact structure contacts the second conductive layer; and
a conductive structure comprising a first body, wherein the first body surrounds the first contact structure and extends into the first semiconductor structure along the first direction, and the first body and the first conductive layer are separated by a dielectric layer.

12. The semiconductor device of claim 11, wherein a first end of the first conductive layer and a first end of the second conductive layer are offset along a second direction perpendicular to the first direction.

13. The semiconductor device of claim 12, wherein the second contact structure and the second body are between the first end of the first conductive layer and the first end of the second conductive layer along the second direction.

14. The semiconductor device of claim 11, further comprising:
one or more bonding structures comprising a first bonding structure between the first semiconductor structure and the second semiconductor structure, wherein:
the conductive structure further comprises a base and a second body;
the base is perpendicular to the first direction;
the second contact structure extends through the first bonding structure;
the second body surrounds the second contact structure, extends through the first bonding structure along the first direction, and contacts the base; and
a dielectric material is between the second body and the first conductive layer, and between the second body and the second conductive layer.

15. A method of fabricating a semiconductor device, comprising:
forming a first semiconductor structure and second semiconductor structure stacked along a first direction, wherein the first semiconductor structure comprises a first conductive layer, the second semiconductor structure comprises a second conductive layer;
forming a first contact structure and a second contact structure extending along the first direction, wherein the first contact structure extends into the first semiconductor structure and contacts the first conductive layer, the second contact structure contacts the second conductive layer; and
forming a conductive structure comprising a first body, wherein the first body surrounds the first contact structure and extends into the first semiconductor structure, and the first body and the first conductive layer are separated by a dielectric layer.

16. The method of claim 15, further comprises:
forming a first bonding structure between the first semiconductor structure and the second semiconductor structure along the first direction;
forming a first contact hole and a second contact hole extending along the first direction, wherein the first contact hole extends into the first semiconductor structure and reaches the first conductive layer, and the second contact hole extends through the first bonding structure and reaches the second conductive layer; and
forming a first dielectric layer by depositing a dielectric material on top of the first semiconductor structure and in the first contact hole and the second contact hole.

17. The method of claim 16, wherein:
the first conductive layer is aligned with the second conductive layer along the first direction;
the second contact hole extends through the first conductive layer; and
forming the first contact hole and the second contact hole comprises:
forming the first contact hole and a first portion of the second contact hole by a first etching process, wherein the first contact hole and the first portion of the second contact hole both reach the first conductive layer;
filling the first contact hole and the first portion of the second contact hole with a filler material;
forming a mask on top of the first semiconductor structure, wherein the mask covers an opening of the first contact hole and comprises a pattern that matches an opening of the second contact hole;
removing the filler material in the first portion of the second contact hole;
forming the second contact hole by a second etching process, wherein the second contact hole reaches the second conductive layer; and
removing the mask and the filler material in the first contact hole.

18. The method of claim 16, wherein:
a first end of the first conductive layer and a first end of the second conductive layer are offset along a second direction perpendicular to the first direction;
the second contact hole is between the first end of the first conductive layer and the first end of the second conductive layer along the second direction;
the second contact hole does not extend through the first conductive layer; and
forming the first contact hole and the second contact hole comprises forming the first contact hole and the second contact hole by a same etching process.

19. The method of claim 16, wherein forming the conductive structure comprises:
forming a conductive structure by depositing a conductive material on top of the first dielectric layer; and
etching off a bottom portion of the conductive structure and the first dielectric layer in the first contact hole and a bottom portion of the conductive structure and the first dielectric layer in the second contact hole by a third etching process, wherein the third etching process exposes the first conductive layer in the first contact hole and exposes the second conductive layer in the second contact hole, wherein the first body of the conductive structure is formed by the conductive structure in the first contact hole, a second body of the conductive structure is formed by the conductive structure in the second contact hole, and a base of the conductive structure is formed by a remaining portion of the conductive structure on top of the first semiconductor structure.

20. The method of claim 19, further comprising:
forming a second dielectric layer by depositing the dielectric material on top of the first semiconductor structure and in the first contact hole and the second contact hole; and
etching off a bottom portion of the second dielectric layer in the first contact hole and a bottom portion of the second dielectric layer in the second contact hole by a fourth etching process, wherein the fourth etching process exposes the first conductive layer in the first contact hole and exposes the second conductive layer in the second contact hole.
